(19) United States
(12) Patent Application Publication
(10) Pub. No.: US 2018/0153044 A1
(43) Pub. Date: May 31, 2018

(54) WIRING SUBSTRATE METHOD OF MANUFACTURING, WIRING SUBSTRATE AND WIRING SUBSTRATE MANUFACTURING DEVICE

(71) Applicant: USHIO DENKI KABUSHIKI KAISHA, Tokyo (JP)

(72) Inventors: Tomoyuki HABU, Tokyo (JP); Shinichi ENDO, Tokyo (JP); Masahito NAMAI, Tokyo (JP); Akira AIBA, Tokyo (JP); Hiroko MATSUMOTO, Tokyo (JP); Hiroki HORIBE, Tokyo (JP); Shun MARUYAMA, Tokyo (JP)

(73) Assignee: USHIO DENKI KABUSHIKI KAISHA, Tokyo (JP)

(21) Appl. No.: 15/736,672

(22) PCT Filed: Apr. 1, 2016
(86) PCT No.: PCT/JP2016/001885

§ 371 Date: Dec. 14, 2017

(30) Foreign Application Priority Data
Jun. 18, 2015 (JP) 2015-122687

(51) Int. Cl. H05K 3/16; H05K 3/18; H05K 3/42; H05K 1/03; H05K 3/00

(52) U.S. Cl. CPC H05K 3/16; H05K 3/18; H05K 3/42; H05K 2203/1105; H05K 3/0055; H05K 2203/09; H05K 2203/0292; H05K 1/0373

(57) ABSTRACT

A semiconductor device includes a first MOS transistor and a second MOS transistor of a second conductivity type. The first MOS transistor includes a first main electrode connected to a first potential and a second main electrode connected to a second potential. The second MOS transistor includes a first main electrode connected to a control electrode of the first MOS transistor and a second main electrode connected to the second potential. The control electrodes of the first and second MOS transistors are connected in common. The first and second MOS transistors are formed on a common wide bandgap semiconductor substrate. In the first MOS transistor, a main current flows in a direction perpendicular to a main surface of the wide bandgap semiconductor substrate. In the second MOS transistor, a main current flows in a direction parallel to the main surface of the wide bandgap semiconductor substrate.

### TECHNICAL FIELD

The present invention relates to a method of manufacturing a wiring substrate, a wiring substrate manufactured by the method thereof, and a device for manufacturing a wiring substrate, the wiring substrate being configured by laminating or layering an insulating layer and a conductive layer.

### BACKGROUND ART

Conventionally, as a wiring substrate to which a semiconductor device or chip, such as a semiconductor integrated circuit or the like, is mounted, a multi-layered wiring substrate has been known in which an insulating layer and a conductive layer (that is, a wiring layer) are alternately laminated.

As an exemplarily manufacturing process for the multi-layered wiring substrate, first, a drill machining or a laser machining is applied to a wiring substrate material having a conductive layer and an insulating layer that is laminated on the conductive layer, and the insulating layer or a part of the conductive layer is removed therefrom so as to form a via hole or a through hole.

At this point, a smear (that is, a residue) is generated on the wiring substrate material caused by the material constituting the insulating layer or the conductive layer. For this reason, a desmear treatment (desmearing) is applied to the wiring substrate material in order to remove the smear.

Subsequently, a seed layer is formed on the insulating layer or an inner face of the via hole or the like, and a resist pattern is formed on the insulating layer. Then, a conductive material is laminated thereon by way of the electrolytic plating. Yet subsequently, the resist pattern and the seed layer are removed therefrom so as to fabricate a semiconductor circuit pattern. Furthermore various processes may be performed and resultantly a semiconductor device is fabricated.

Patent Literature 1 (Laid-open Publication of Japanese Patent Application No.2003-318519 A) discloses a method of manufacturing a substrate including a step of removing a smear generated in a via forming step by way of a wet type desmear treatment, and a step of forming a seed layer by way of a non-electrolytic plating.

### LISTING OF REFERENCES

### Patent Literature

PATENT LITERATURE 1: Laid-open Publication of Japanese Patent Application No.2003-318519 A

### SUMMARY OF THE INVENTION

### Problems to be Solved by the Invention

According to the above mentioned Patent Literature 1 (Laid-open Publication of Japanese Patent Application No.2003-318519 A), a seed layer is formed by way of the non-electrolytic plating after the desmear treatment is applied. In order to ensure the adhesiveness or bonding property between the seed layer and the insulating layer, it is required to roughen a surface of the insulating layer as appropriate to a rough or coarse state and to firmly secure the seed layer to the surface of the insulating layer by way of the anchor effect.

For this reason, according to the technique disclosed in the above mentioned Patent Literature 1 (Laid-open Publication of Japanese Patent Application No.2003-318519 A), the surface of the insulating layer is roughened by applying the wet type desmear treatment as the desmear treatment.

In the meantime, recent years, the semiconductor device has been more and more downsized, thus the wiring substrate is also required to be miniaturized. However, when the surface of the insulating layer is roughened in order to achieve the above mentioned anchor effect, it is turned out that a wiring pattern to be formed on the roughened surface of the insulating layer, in particular, a fine or microscopic wiring pattern having a line/space (L/S) equal to or less than 10/10 μm, cannot be formed any more. As a result, it makes it impossible to miniaturize the wiring substrate.

Taking the above mentioned circumstances into consideration, the present invention has been made in order to solve the above mentioned problems and an object thereof is to provide a method of manufacturing a wiring substrate, a wiring substrate and a device for manufacturing a wiring substrate that are capable of achieving the miniaturization of a wiring pattern while ensuring the tight adhesiveness between the seed layer and the insulating layer.

### Solution to Problems

In order to solve the above mentioned problems, according to one aspect of a method of manufacturing a wiring substrate of the present invention, there is provided a method of manufacturing a wiring substrate, comprising: a first step of forming a through hole on a wiring substrate material having a conducive layer and an insulating layer laminated on the conductive layer, the through hope penetrating through the insulating layer; a second step of applying a desmear treatment to the wiring substrate material by irradiating the wiring substrate material in which the through hole is formed with ultra violet light having a wavelength equal to or less than 220 nm; a third step of forming a seed layer inside the through hole and on the insulating layer to which the desmear treatment is applied by causing material particles to collide against and adhere to the through hole and the insulating layer; and a fourth step of forming a plated layer made of a conductive material on the seed layer by an electrolytic plating.

According to the above mentioned method, in this way, it makes it possible to prevent a surface of the insulating layer from being roughened as the desmear treatment by using the ultra violet light is applied. For this reason, it makes it possible to form the fine wiring pattern in an appropriate manner. Also, the seed layer is formed by causing the material particles to collide against and adhere to the insulating layer. For this reason, it makes it possible to ensure the adhesion strength of the seed layer to the insulating layer without relying on the anchor effect unlike the conventional technique.

In particular, it makes it possible to cause a color center (that is, a structural defect or a bond defect) to be generated on the surface of the insulating layer by irradiating the insulating layer with the ultra violet light having the wavelength equal to or less than 220 nm that is non-transmissive through the insulating layer. At this point, the material particles (that is, a conductive material) are driven or hit into the insulating layer to exert energy to the bond defect portion that resides in a resin surface irradiated with the ultra violet light.

As a result, the chemical binding action (bonding property) is newly created between the metal particles and the resin. Resultantly, it makes it possible to create the seed layer that has stronger adhesive force as compared to the case in which the metal particles collide against and attach to a resin that is not irradiated with the ultra violet light having the wavelength equal to or less than 220 nm.

In the above mentioned method of the wiring substrate, in the third step, the seed layer may be formed by a sputtering method, or alternatively may be formed by an ion plating method. By doing this, it makes it possible to form the seed layer with the higher adhesiveness to the insulating layer being ensured.

Furthermore, in the above mentioned method of the wiring substrate, the insulating layer may be made of a resin containing a particulate or granular filler, and the second step may include a step of irradiating the wiring substrate material with the ultra violet light, and a step of imparting a physical vibration or oscillation to the wiring substrate material irradiated with the ultra violet light. By doing this, a smear caused by an organic substance can be decomposed by the irradiation with the ultra violet light, and a smear caused by an inorganic substance can be decomposed by the physical vibration. In this way, it makes it possible to remove any smear caused by either the organic substance or the inorganic substance in an assured manner.

Yet furthermore, in the above mentioned method of manufacturing the wiring substrate, in the second step, the wiring substrate material may be irradiated with the ultra violet light while heating the wiring substrate material in an atmosphere of a processing gas containing oxygen. In this way, by irradiating the wiring substrate material with the ultra violet light in the atmosphere of the processing gas containing oxygen, ozone or active oxygen can be generated. Thus, it makes it possible to effectively remove the smear.

In addition, as the wiring substrate material is irradiated while the wiring substrate material is being heated, it makes it possible to accelerate the reaction rate or velocity between the smear and the ozone or the active oxygen so as to accelerate the desmear treatment speed (that is, the speed to remove the smear).

Yet furthermore, in the above mentioned method of manufacturing the wiring substrate, the first step may be a step of forming the through hole in the wiring substrate material having a protective layer on the insulating layer, the through hole penetrating through the protective layer and the insulating layer. Also, in the second step, the desmear treatment may be applied to an inside of the through hole by irradiating the wiring substrate material with the ultra violet light with the protective layer serving as a mask, and in the third step, the seed layer may be formed after removing the protective layer.

Yet furthermore, in the above mentioned method of manufacturing the wiring substrate, the first step may include a step of forming the protective layer on the insulating layer, and a step of forming the through hole penetrating through the protective layer and the insulating layer.

According to the above mentioned method, it makes it possible to suppress the surface of the insulating layer from being roughened to the minimum, and to form the fine wiring pattern with the higher accuracy.

Yet furthermore, according to one aspect of a wiring substrate of the present invention, the wiring substrate is manufactured by any one of the above mentioned methods of manufacturing the wiring substrate. Thus, the wiring substrate is allowed to be a fine wiring substrate having a higher reliability with the adhesiveness between the seed layer and the insulating layer being ensured.

Still yet furthermore, according to one aspect of a wiring substrate manufacturing device of the present invention, the wiring substrate manufacturing device comprises: a ultra violet irradiation unit configured to irradiate a wiring substrate material with ultra violet light having a wavelength equal to or less than 220 nm, the wiring substrate material having a conductive layer, an insulating layer made of a resin containing a particulate filler and laminated on the conductive layer, and a through hole being formed to penetrate through the insulating layer; a vibration imparting unit configured to impart a physical vibration to the wiring substrate material irradiated with the ultra violet light by the ultra violet light irradiation unit; and a seed layer forming unit configured to form a seed layer inside the through hole and on the insulating layer to which the desmear treatment is applied by the ultra violet light irradiation unit and the vibration imparting unit by causing material particles to collide against and adhere to the through hole and the insulating layer.

According to the above mentioned device, it makes it possible to manufacture the wiring substrate having a higher reliability with the adhesiveness between the seed layer and the insulating layer being ensured.

### Advantageous Effect of the Invention

According to a method of manufacturing a wiring substrate, a wiring substrate and a wiring substrate manufacturing device of the present invention, it makes it possible to accomplish the miniaturization of the wiring pattern while assuring the tight adhesiveness between the seed layer and the insulating layer. As a result, it makes it possible to manufacture a fine wiring substrate having a higher reliability.

The above mentioned and other not explicitly mentioned objects, aspects and advantages of the present invention will become apparent to a skilled person from the following embodiments (detailed description) when read and understood in conjunction with the appended claims and drawings.

### BRIEF DESCRIPTION OF DRAWINGS

FIG. 1A is a schematic view showing an exemplary method of manufacturing a wiring substrate according to a present embodiment.

FIG. 1B is a schematic view showing the exemplary method of manufacturing the wiring substrate according to the present embodiment.

FIG. 1C is a schematic view showing the exemplary method of manufacturing the wiring substrate according to the present embodiment.

FIG. 1D is a schematic view showing the exemplary method of manufacturing the wiring substrate according to the present embodiment.

FIG. 1E is a schematic view showing the exemplary method of manufacturing the wiring substrate according to the present embodiment.

FIG. 1F is a schematic view showing the exemplary method of manufacturing the wiring substrate according to the present embodiment.

FIG. 1G is a schematic view showing the exemplary method of manufacturing the wiring substrate according to the present embodiment.

FIG. 1H is a schematic view showing the exemplary method of manufacturing the wiring substrate according to the present embodiment.

FIG. 2 is a graph showing a characteristic of an ultra violet light transmittance or transmission rate of an epoxy resin.

FIG. 3A is a schematic view showing a state in which an exemplarily wiring substrate material is irradiated with the ultra violet light having a wavelength equal to or less than 220 nm.

FIG. 3B is a schematic view showing a state in which the sputtering is performed to a resin irradiated with the ultraviolet light having the wavelength equal to or less than 220 nm.

FIG. 3C is an enlarged schematic view of a surface of the insulating layer when the sputtering is performed to the resin irradiated with the ultra violet light having the wavelength equal to or less than 220 nm.

FIG. 4A is a schematic view showing a state in which a wiring substrate material is irradiated with ultra violet light having a wavelength of 250 nm.

FIG. 4B is a schematic view showing a state in which the sputtering is performed to the resin irradiated with ultra violet light having the wavelength of 250 nm.

FIG. 4C is an enlarged schematic view of a surface of the insulating layer when the sputtering is performed to the resin irradiated with the ultra violet light having the wavelength of 250 nm.

FIG. 5A is a schematic view explaining the evaluation of the via connection or bonding strength.

FIG. 5B is a schematic view explaining the evaluation of the via connection strength.

FIG. 5C is a schematic view explaining the evaluation of the via connection strength.

FIG. 5D is a schematic view explaining the evaluation of the via connection strength.

FIG. 6A is a schematic view showing an exemplary configuration of a wiring substrate manufacturing device.

FIG. 6B is a schematic view showing another exemplary configuration of a wiring substrate manufacturing device.

### DESCRIPTION OF EMBODIMENTS

Hereinafter, embodiments of the present invention will be described with reference to the accompanying drawings in detail.

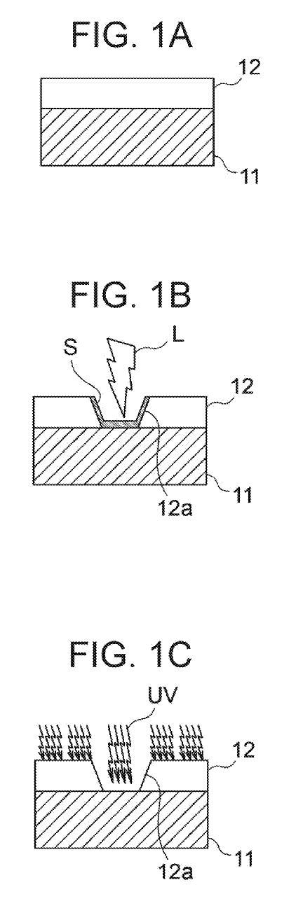

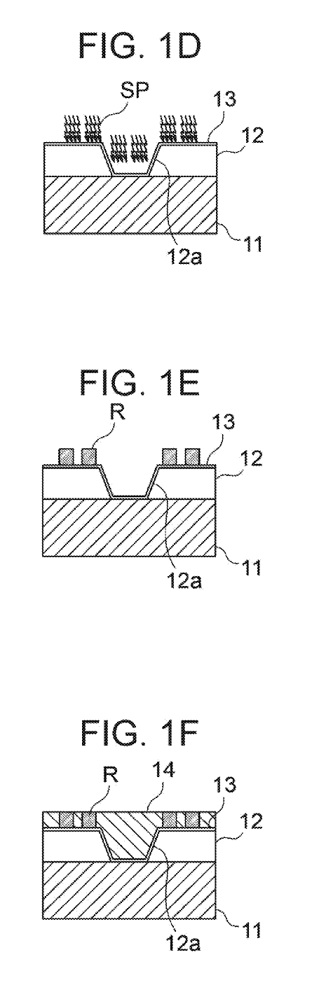

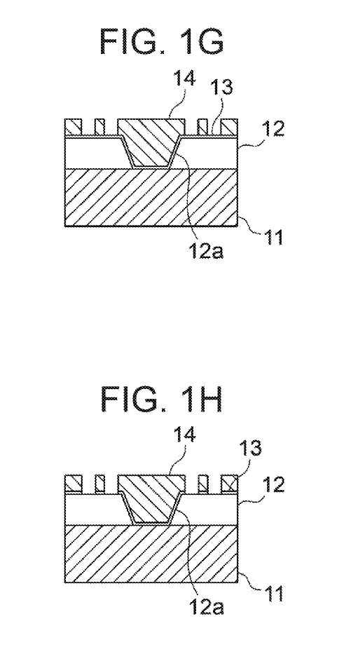

FIGS. 1A to 1H are schematic views showing an exemplary method of manufacturing a wiring substrate according to the present embodiment, respectively. According to the present embodiment, a wiring substrate to be manufactured is a multi-layered wiring substrate in which a conductive layer (that is, a wiring layer) and an insulating layer are laminated on a core substrate. The core substrate is made of, for example, a glass epoxy resin or the like. As a material constituting the conductive layer (wiring layer), for example, copper, nickel or gold or the like may be used.

The insulating layer is made of, for example, a resin or the like containing a particulate filler made of an inorganic substance. As such a resin, for example, an epoxy resin, bismaleimide triazine resin, a polyimide resin, a polyester resin or the like may be used. Also, as the material constituting the particulate filler, for example, silica, alumina, mica, silicate, barium sulfate, magnesium hydroxide, titanium oxide or the like may be used.

When manufacturing the multi-layered wiring substrate, first, as shown in FIG. 1A, a wiring substrate material is formed by laminating a conductive layer 11 on an insulating layer 12. As a method of forming the insulating layer 12 on the conductive layer 11, for example, a certain method of applying an insulating layer forming material containing the particulate filler to a thermoset resin in a liquid state, and subsequently hardening or curing the insulating layer forming material may be used. Alternatively, a method of bonding an insulation sheet containing the particulate filler by way of the thermal compression bonding or the like.

Subsequently, as shown in FIG. 1B, a via hole 12a having a depth reaching to the conductive layer 11 is formed by, for example, machining the insulating layer 12 by using a laser L. As a method for the laser machining, for example, a method of using a CO₂ laser or a method of a UV laser or the like may be used. It should be noted that a method of forming the via hole 12a is not limited to the laser machining. For example, alternatively, a drill machining or the like may be used.

After the via hole 12a is formed in this way, a smear (residual) S caused by the material constituting the conductive layer 11 or the insulating layer 12 is generated on an inner wall face (side wall) of the via hole 12a in the insulating layer 12, a peripheral region of the via hole 12a on a surface of the insulating layer 12, and a bottom portion of the via hole 12a (in other words, an exposed portion of the conductive layer 11 by the via hole 12a) or the like.

For this reason, as shown in FIG. 1C, a treatment to remove the smear S (that is, a desmear treatment) is applied. According to the present embodiment, as the desmear treatment, so-called photo desmear treatment is employed in which the smear S is removed by irradiating a portion to be treated with the ultra violet light (UV).

More particularly, the photo desmear treatment includes an ultra violet light irradiation process, which irradiates the portion to be treated of the wiring substrate material with the above mentioned ultra violet light, and a physical vibration imparting process, which imparts the physical vibration to the wiring substrate material after the ultra violet light irradiation process.

Hereinafter, the above mentioned photo desmear treatment will be described in detail.

The ultra violet light irradiation process may be performed in an atmosphere containing oxygen, such as atmospheric air. As the ultra violet light sources, various lamps that emit the ultra violet light (vacuum ultra violet light) having a wavelength equal to or less than 220 nm, preferably equal to or less than 190 nm, may be used. The reason why the wavelength of 220 nm is employed is because, when the wavelength of the ultra violet light exceeds 220 nm, it makes it difficult to decompose and remove a smear caused by the organic substance such as a resin or the like.

The smear caused by the organic substance is decomposed by the ozone or the active oxygen associated with the energy of the ultra violet light and the irradiation of the ultra violet light, which is generated by being irradiated with the ultra violet light having the wavelength equal to or less than 220 nm in the ultra violet light irradiation process.

In addition, another smear caused by the inorganic substance, in particular, silica or alumina, becomes brittle by being irradiated with the ultra violet light.

As the ultra violet light source, for example, a xenon excimer lamp enclosing a xenon gas (having a peak wavelength of 172 nm) or a low pressure mercury lamp (having a bright line at 185 nm) or the like may be used. Inter alia, for applying the desmear treatment, for example, the xenon excimer lamp is preferable to be used.

In an ultra violet light irradiation device configured to perform the above mentioned ultra violet light irradiation process, a processing region, in which the wiring substrate material serving as an object to be treated is exposed to the ultra violet light in an atmosphere of a processing gas containing oxygen, is heated, for example, to the temperature within a range between 120 degrees Celsius and 190 degrees Celsius (for example, 150 degrees Celsius).

Also, the clearance between an ultra violet light emitting window and the wiring substrate material serving as the object to be treated is set to, for example, 0.3 mm. It should be noted that the illuminance of the ultra violet light or the irradiation time of the ultra violet light or the like may be set as appropriate in consideration of the residual state of the smear S or the like.

Next, the physical vibration imparting process may be performed by, for example, an ultrasonic vibration process. The frequency of the ultrasonic wave in the ultrasonic vibration process is preferably, for example, within a range between 20 kHz and 70 kHz. This is because, when the frequency of the ultrasonic wave exceeds 70 kHz, then it makes it difficult to destruct the smear caused by the inorganic substance to cause the destructed smear to separate from the wiring substrate material.

In the above mentioned ultrasonic vibration process, as a vibration medium of the ultrasonic wave, liquid such as water and gas such as air or the like may be used.

More particularly, when water is used as the vibration medium, the ultrasonic vibration process may be performed by immersing the wiring substrate material in, for example, water, and ultrasonic-vibrating the water with the wiring substrate material being immersed therein. When liquid is used as the vibration medium, the processing time of the ultrasonic vibration process is, for example, between 10 seconds and 600 seconds.

When air is used as the vibration medium, the ultrasonic vibration process may be performed by spraying compressed air onto the wiring substrate material while ultrasonic-vibrating the compressed air. When the compressed air is used as the vibration medium, the pressure of the compressed air is preferably, for example, equal to or greater than 0.2 MPa. Also, the processing time of the ultrasonic vibration process using the compressed air is, for example, between 5 seconds and 60 seconds.

The above mentioned ultra violet light irradiation process and the physical vibration imparting process may be performed once per each process in this order, respectively. Nevertheless, it is preferable to alternately perform the ultra violet light irradiation process and the physical vibration imparting process in a repetitive manner. When repeating the above mentioned processes, the repeat count of the ultra violet light irradiation process and the physical vibration imparting process may be set as appropriate in consideration of the irradiation time in respective ultra violet light irradiation processes, and may be, for example, between once to five times.

As described above, in the ultra violet light irradiation process, the ozone or the active oxygen is generated by irradiating the processing gas containing oxygen with the ultra violet light having the wavelength equal to or less than 220 nm. Thus, the smear S caused by the organic substance is decomposed to be gasified by the ozone or the active oxygen. As a result, the majority of the smears S caused by the organic substance is removed. At this point, another smear S caused by the inorganic substance is exposed after the smear S caused by the organic substance is removed, and then becomes brittle with the smear S caused by the inorganic substance being irradiated with the ultra violet light.

Subsequently, by performing the physical vibration imparting process in this state, the exposed smear S caused by the inorganic substance or the residual smear S caused by the organic substance is destroyed and then removed by the mechanical action using the vibration.

Alternatively, a slight gap is created between smears because the smears S caused by the inorganic substance are contracted or the difference in thermal expansion occurs when irradiating the respective smears S with the ultra violet light. For this reason, the smear S caused by the inorganic substance is separated from the wiring substrate material by applying the physical vibration imparting process. As a result, it makes it possible to completely remove both the smear S caused by the inorganic substance and the smear S caused by the organic substance from the wiring substrate material.

According to the photo desmear treatment of the present embodiment, it is sufficient to apply the desmear treatment by performing the ultra violet light irradiation process and the physical vibration imparting process to the wiring substrate material. Thus, it is not required to use chemicals that require the liquid waste disposal.

After the photo desmear treatment is completed, as shown in FIG. 1D, a seed layer 13 is formed on an upper face of the insulating layer 12 and an inner face of the via hole 12a. According to the present embodiment, the sputtering (SP) is employed as a method of forming the seed layer 13. For example, in order to assure the adhesiveness strength, first, a base layer (approximately between 10 nm to 100 nm) is formed using titanium (Ti) as a target material. Subsequently, the seed layer (approximately between 100 nm and 1000 nm) is formed using copper (Cu) as the target material.

Yet subsequently, as shown in FIG. 1E, a resist pattern R is formed on the seed layer 13. As a method of forming the resist pattern R, for example, a method that applies the resist on the seed layer 13 and then forms the pattern by way of the lithographic exposure and/or the image development.

Yet subsequently, as shown in FIG. 1F, a plated layer 14 is formed from an inside of the via hole 12a to an opening portion of the resist pattern R by way of the electrolytic plating which uses the seed layer 13 for the power supply path for the metal plating. As the plated layer 14, for example, a layer (approximately between 20 μm and 50 μm) made of, for example, copper (Cu) or the like may be used.

Lastly, as shown in FIG. 1G, the resist pattern R is removed, and then, as shown in FIG. 1H, the seed layer 13 is removed with the plated layer 14 being used as the mask (flash etching).

It should be noted that, among the above described processes, the process shown in FIG. 1B corresponds to a first step of forming the through hole in the insulating layer laminated on the conductive layer, and the process shown in FIG. 1C corresponds to a second step of applying the desmear treatment by irradiating the insulating layer and the through hole with the ultra violet light having a wavelength equal to or less than 220 nm after the first step. Also, the process shown in FIG. 1D corresponds to a third step of forming the seed layer by the sputtering method inside the through hole and on the insulating layer after the second step, and the process shown in FIG. 1F corresponds to a fourth step of forming the plated layer made of the conductive material on the seed layer by use of the electrolytic plating.

As described above, according to the present embodiment, the smear S is removed using the photo desmear treatment, and subsequently the seed layer 13 is formed by the sputtering method.

Conventionally, the adhesiveness between the insulating layer and the seed layer has been assured by using the anchor effect. In other words, it has been considered that the surface of the insulating layer is preferably to be roughened in order to assure the adhesiveness between the insulating layer and the seed layer.

However, when the surface of the insulating layer is roughened, it makes it impossible to form the fine wiring pattern having, in particular, the line/space (L/S) equal to or less than 10/10 μm. Thus, it makes it difficult to fabricate the fine wiring substrate. For this reason, in order to fabricate the fine wiring substrate, it is required to assure the tight adhesiveness between the insulating layer and the seed layer without the surface of the insulating layer being roughened.

The inventor(s) of the present invention have conceived that the tight adhesiveness between the insulating layer and the seed layer can be assured without the surface of the insulating layer being roughened by applying the desmear treatment and the seed layer forming process, which are a part of a manufacturing process of the wiring substrate, by combining the photo desmear treatment and the sputtering method.

The photo desmear treatment is capable of removing the smear without a surface of an object to be treated being roughened. In addition, according to the photo desmear treatment of the present embodiment, as the physical vibration imparting process is performed subsequently to the ultra violet light irradiation process, it makes it possible to remove both the smear caused by the organic substance and the smear caused by the inorganic substance in an appropriate manner.

Moreover, as the seed layer 13 is formed by use of the sputtering method, it makes it possible to form the seed layer 13 on the insulating layer 12 of which surface is not roughened with the sufficient adhesive strength.

In particular, as the ultra violet light having the wavelength equal to or less than 220 nm is used in the ultra violet light irradiation process and then the seed layer forming process using the sputtering method is performed after the ultra violet light irradiation process, it makes it possible to densely and firmly form the seed layer 13 on the insulating layer 12. Hereinafter, the above mentioned mechanism will be described in detail.

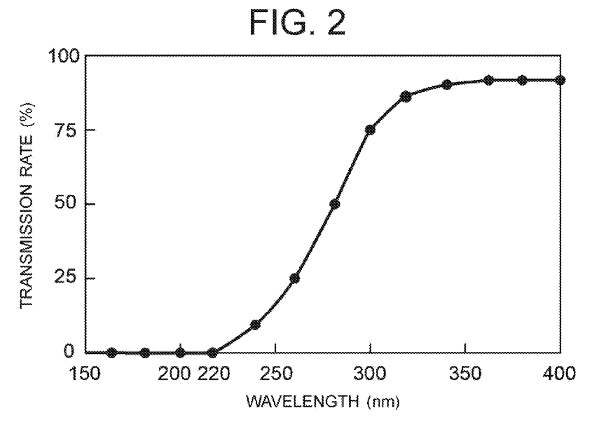

FIG. 2 is a graph showing the transmission rate characteristic of the ultra violet light with respect to the epoxy resin (25 μm film). In FIG. 2, the horizontal axis denotes the wavelength of the ultra violet light (nm) and the vertical axis denotes the transmission rate or transmittance of the ultra violet light (%).

As shown in FIG. 2, in a region having the wavelength equal to or greater than 220 nm, in other words, a part of the visible light and near-ultra violet light regions, the light passes through the resin, and the transmission rate thereof becomes smaller as the wavelength becomes shorter.

In particular, in a region having the wavelength exceeding 300 nm, the light almost completely passes through the resin. On the other hand, in a region having the wavelength equal to or less than 300 nm, the ultra violet light is absorbed by the resin to a certain extent, however, the absorption thereof is not as much as the ultra violet light is completely intercepted or shielded by the resin. This is because the resin absorbs the ultra violet light in the entire thickness direction. Thus, the portion of the resin that is excited by the absorbed ultra violet light is distributed broadly in an entire resin.

On the other hand, the ultra violet light having the wavelength equal to or less than 220 nm does not pass through the resin. The absorbance thereof is high thus the ultra violet light is absorbed by a surface layer of the resin. When the wavelength of the ultra violet light becomes further shorter, the ultra violet light is completely absorbed by a top surface of the resin. And the excited portion generated by the absorbed ultra violet light is distributed in a surface of the resin in laminae (in a layered manner).

Then, by way of the energy produced when incoming target particles, which is sputtered by the sputtering method, are driven into the resin, the above mentioned activated resin portion newly creates a bond or cohesion with the target particles so as to firmly fixate the target particles.

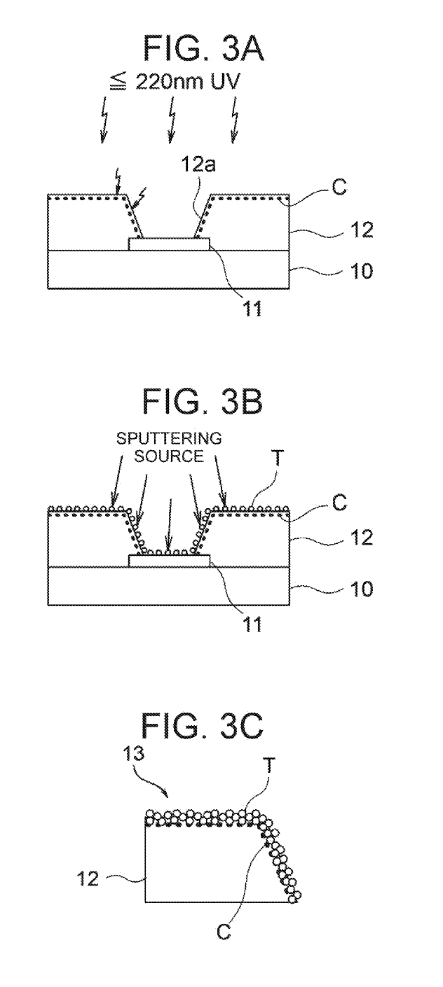

FIGS. 3A to 3C are views showing respective states when the sputtering is applied to the resin that is irradiated with the ultra violet light having the wavelength equal to or less than 220 nm. In FIG. 3A, illustrated is a part of the wiring substrate material that is configured to include an insulating layer 10, a conductive layer 11 having a desired pattern and laminated on a surface of the insulating layer 10, and an insulating layer 12 laminated on the insulating layer 10 including the conductive layer 11.

When the ultra violet light (UV) having the wavelength equal to or less than 220 nm, as shown in FIG. 3A, as the photo desmear treatment for removing the smear residual in the via hole 12a (not shown), as described above, the ultra violet light is absorbed by the surface of the insulating layer 12, and the color center (binding defect or structural defect) C is generated in the surface of the insulating layer 12. The color center C is a defect that is generated in a way in which the surface of the resin is excited by the absorbed ultra violet light so as to cut the chemical bond between atoms or to change the binding state.

As shown in FIG. 3B, when the incoming target particles (metal particles) T from the sputtering source is driven into the surface of the insulating layer 12 in which the color center C is being generated in this way, then the color center C firmly captures the metal particles T. In other words, the chemical binding action is newly created between the metal particles and the resin with the energy being applied to the binding defect portion that resides in the surface of the resin irradiated with the ultra violet light. FIG. 3C is an enlarged view of the surface of the insulating layer 12 at this point. As described above, the adhesiveness becomes extremely firm between the insulating layer 12, which is irradiated with the ultra violet light having the wavelength equal to or less than 220 nm, and the metal film, to which the sputtering is applied (the seed layer 13 in FIG. 1D).

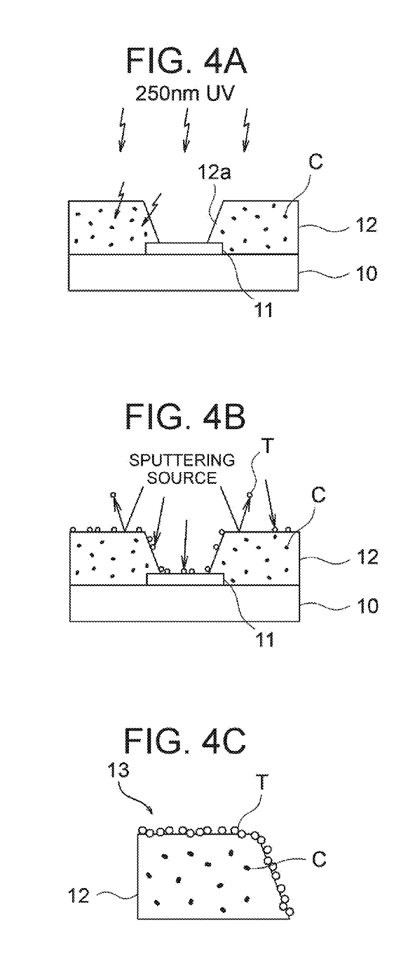

In contrast, when the ultra violet light having the wavelength, for example, of 250 nm as the photo desmear treatment, with respect to the wiring substrate material similar to the wiring substrate material as shown in FIG. 3A, then in the insulating layer 12 irradiated with the ultra violet light, the excited resin is distributed in a non-dense manner across the entire insulating layer 12. In other words, as shown in FIG. 4A, the color center C is not distributed only in the surface of the insulating layer but distributed inside the entire insulating layer 12.

For this reason, as shown in FIG. 4B, even when the incoming target particles (metal particles) T from the sputtering source are driven into the surface of the insulating layer 12, the surface of the insulating layer 12 is less likely to capture the metal particles T. In other words, as shown in an enlarged view of the surface of the insulating layer 12 at this point in FIG. 4C, a particular binding action is not created between the surface of the insulating layer 12 and the metal particles T. For this reason, the adhesiveness of the metal film (the seed layer 13 in FIG. 1D) formed on the insulating layer 12 is not intensified.

As described above, according to the present embodiment, the ultra violet light having the wavelength equal to or less than 220 nm is used in the ultra violet light irradiation process, and the seed layer forming process is performed using the sputtering method after the ultra violet light irradiation process. Thus, it makes it possible to form the seed layer 13 on the insulating layer 12 in a dense and firm manner. As a result, the plated layer 14, which is formed by applying the electrolytic plating onto the seed layer 13, demonstrates a higher adhesiveness with the insulating layer 12. In this way, it makes it possible to ensure the adhesiveness between the insulating layer 12 and the seed layer 13 without the surface of the insulating layer being roughened. Resultantly, it makes it possible to accomplish the fine wiring substrate with higher reliability.

Furthermore, as the surface of the insulating layer 12 can be kept to be smooth, it also makes it possible to improve the high frequency responsiveness. When the frequency becomes higher, a signal tends to have a characteristic to concentrate within a surface of a conductor due to the skin effect. In this regard, as the above mentioned conventional technique, when the surface of the insulating layer 12 is roughened in order to obtain the anchor effect, then the transmission distance of the signal is made longer, which makes the transmission loss larger and the responsiveness worse. In contrast, according to the present embodiment, it makes it possible to reduce the above mentioned transmission loss and to improve the responsiveness.

### WORKING EXAMPLES

Hereinafter, working examples that were carried out in order to confirm the effect of the present embodiment will be described in detail.

### [Wiring Substrate Material]

First, a laminated body was prepared which was fabricated by vacuum laminating the epoxy resin of 25 μm on a core material of a prepreg made of a glass epoxy resin and copper on both sides thereof and applying the high pressure press and the baking to the vacuum-laminated core material.

By applying the laser machining by a via machining equipment (a CO₂ laser or a UV laser) to the layered body, blind via holes were created in a grid shape at the pitch of 500 μm. The opening diameter of the via hole was set to either φ50 μm or φ25 μm. In this way, a wiring substrate material was obtained. In addition, at this point, the residual smear was confirmed to reside on a bottom portion of the blind via hole of the wiring substrate material.

### Referential Example 1

A wiring substrate material in which via holes each having a via opening diameter of φ50 μm were formed by using a CO₂ laser was used. A wet desmear treatment using a permanganic acid solution was applied to the wiring substrate material. Subsequently, a Cu layer of 30 μm (a plated layer) was formed by using the electrolytic plating on the substrate on which a seed layer of 1 μm was formed by the non-electrolytic copper plating.

### Comparative Example 1

A wiring substrate material in which via holes each having a via opening diameter of φ50 μm were formed by using a CO₂ laser was used. A wet desmear treatment using a permanganic acid solution was applied to the wiring substrate material. Subsequently, a Cu layer of 30 μm (a plated layer) was formed by using the electrolytic plating on the substrate on which a seed layer of 0.33 μm (Ti/Cu: 0.03 μm/0.3 μm) was formed by the sputtering method.

### Working Example 1

A wiring substrate material in which via holes each having a via opening diameter of φ50 μm were formed by using a CO₂ laser was used. A photo desmear treatment using ultra violet light having the wavelength of 172 nm was applied to the wiring substrate material. Subsequently, a Cu layer of 30 μm (a plated layer) was formed by using the electrolytic plating on the substrate on which a seed layer of 0.33 μm (Ti/Cu: 0.03 μm/0.3 μm) was formed by the sputtering method. It should be noted that, in the photo desmear treatment, the ultra violet light irradiation process and the physical vibration imparting process (ultrasonic vibration process) were carried out.

### Comparative Example 2

A wiring substrate material in which a protective layer of a PET film having the thickness of 38 μm was affixed to the above described laminated body (that is, an epoxy substrate) and subsequently via holes each having a via opening diameter of φ50 μm were formed by using an UV laser was used. A wet desmear treatment using a permanganic acid solution was applied to the wiring substrate material. Then after peeling off the protective layer, a seed layer of 0.33 μm (Ti/Cu: 0.03 μm/0.3 μm) was formed by the sputtering method. Furthermore, a Cu layer of 30 μm (a plated layer) was formed by using the electrolytic plating on the substrate.

### Working Example 2

A wiring substrate material in which a protective layer of a PET film having the thickness of 38 μm was affixed to the above described laminated body (that is, an epoxy substrate) and subsequently via holes each having a via opening diameter of φ50 μm were formed by using an UV laser was used. A photo desmear treatment using ultra violet light having a wavelength of 172 nm was applied to the wiring substrate material. Then after peeling off the protective layer, a seed layer of 0.33 μm (Ti/Cu: 0.03 μm/0.3 μm) was formed by the sputtering method. Furthermore, a Cu layer of 30 μm (a plated layer) was formed by using the electrolytic plating on the substrate. It should be noted that, in the photo desmear treatment, the ultra violet light irradiation process and the physical vibration imparting process (ultrasonic vibration process) were carried out.

### Comparative Example 3

A wiring substrate material in which a protective layer of a PET film having the thickness of 38 μm was affixed to the above described laminated body (epoxy substrate) and subsequently via holes each having a via opening diameter of φ25 μm were formed by using an UV laser was used. A wet desmear treatment using a permanganic acid solution was applied to the wiring substrate material. Then after peeling off the protective layer, a seed layer of 0.33 μm (Ti/Cu: 0.03 μm/0.3 μm) was formed by the sputtering method. Furthermore, a Cu layer of 30 μm (a plated layer) was formed by using the electrolytic plating on the substrate.

### Working Example 3

A wiring substrate material in which a protective layer of a PET film having the thickness of 38 μm was affixed to the above described laminated body (epoxy substrate) and subsequently via holes each having a via opening diameter of φ25 μm were formed by using an UV laser was used. A photo desmear treatment using ultra violet light having a wavelength of 172 nm was applied to the wiring substrate material. Then after peeling off the protective layer, a seed layer of 0.33 μm (Ti/Cu: 0.03 μm/0.3 μm) was formed by the sputtering method. Furthermore, a Cu layer of 30 μm (a plated layer) was formed by using the electrolytic plating on the substrate. It should be noted that, in the photo desmear treatment, the ultra violet light irradiation process and the physical vibration imparting process (ultrasonic vibration process) were carried out.

### Comparative Example 4

A wiring substrate material in which via holes each having a via opening diameter of φ50 μm were formed by using a CO₂ laser was used. A photo desmear treatment using ultra violet light having a wavelength of 254 nm was applied to the wiring substrate material. Subsequently, a Cu layer of 30 μm (a plated layer) was formed by using the electrolytic plating on the substrate on which a seed layer of 0.33 μm (Ti/Cu: 0.03 μm/0.3 μm) was formed by the sputtering method. It should be noted that, in the photo desmear treatment, the ultra violet light irradiation process and the physical vibration imparting process (ultrasonic vibration process) were carried out.

For each of the above mentioned Working Examples 1 to 3, Referential Example 1, and Comparative Examples 1 to 4, a peeling test was carried out in which the Cu layer of the substrate was incised by a cutter knife and then torn off by a tensile strength tester in the direction of 90 degrees in conformity to a method described in JIS H8630 Appendix 1. Then, the peel strength (kg/cm) and the via connection strength (%), which will be described later, were obtained.

In addition, the surface roughness Raₜₒₚ (nm) of the substrate after the desmear treatment was applied, the roughness Raᵥᵢₐ (nm) of a side wall of the via hole, and the opening diameter of the via hole (μm) were measured, respectively. Furthermore, a dry film resist of 7 μm was affixed to the surface of the substrate on which the seed layer was formed to be exposed with the pattern having the line/space (L/S) of 2 μm/2 μm. Finally, developed resist was observed. The results thereof is shown in the following Table 1 (Tables 1-1 and 1-2).

TABLE 1-1

| | Via | | | |
|---|---|---|---|---|
| | diameter | Desmear | Protective | Seed Layer |
| | (μm) | Treatment | Layer | (μm) |
| Referential | Φ50 | Permanganic | N | Non- |
| Example 1 | | acid | | electrolytic |
| | | | | plating |
| Comparative | Φ50 | Permanganic | N | Sputtering |
| Example 1 | | acid | | Ti/Cu: |
| Working | Φ50 | Photo | N | 0.03/0.3 |
| Example 1 | | desmear | | |
| | | (172 nm) | | |
| Comparative | Φ50 | Permanganic | Y | |
| Example 2 | | acid | | |
| Working | Φ50 | Photo | Y | |
| Example 2 | | desmear | | |
| | | (172 nm) | | |
| Comparative | Φ25 | Permanganic | Y | |
| Example 3 | | acid | | |
| Working | Φ25 | Photo | Y | |
| Example 4 | | desmear | | |
| | | (172 nm) | | |
| Comparative | Φ50 | Photo | N | |
| Example 4 | | desmear | | |
| | | (254 nm) | | |

TABLE 1-2

| | | Via | | | Via | |
|---|---|---|---|---|---|---|
| | Peel | Connection | | | Diam- | |
| | Strength | strength | Raₜₒₚ | Raᵥᵢₐ | eter | |
| | (kg/cm) | (%) | (nm) | (nm) | (μm) | Pattern |
| Referential | 0.42 | 100 | 200 | 200 | 60 | No good |
| Example 1 | | | | | | |
| Comparative | 0.45 | 65 | 200 | 200 | 60 | No good |
| Example 1 | | | | | | |
| Working | 0.85 | 100 | 120 | 95 | 52 | Excellent |
| Example 1 | | | | | | |
| Comparative | 0.40 | 72 | 70 | 169 | 57 | Excellent |
| Example 2 | | | | | | |
| Working | 0.62 | 100 | 75 | 70 | 51 | Excellent |
| Example 2 | | | | | | |
| Comparative | 0.40 | 23 | 70 | 120 | 30 | Excellent |
| Example 3 | | | | | | |
| Working | 0.62 | 100 | 80 | 90 | 27 | Excellent |
| Example 4 | | | | | | |
| Comparative | 0.45 | 87 | 100 | 100 | 52 | Excellent |
| Example 4 | | | | | | |

The above mentioned connection strength is calculated to denote a ratio of non-defective items of which via hole status were observed to be non-defectives by using a micro scope through a peeling test with respect to 100 via holes on the substrates fabricated under the same condition.

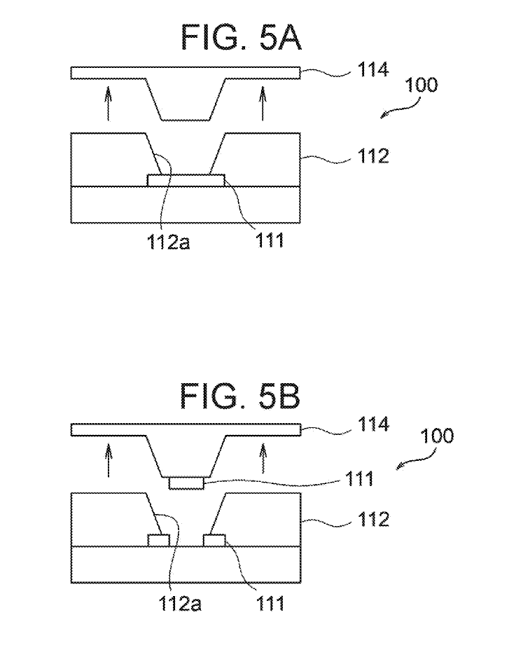

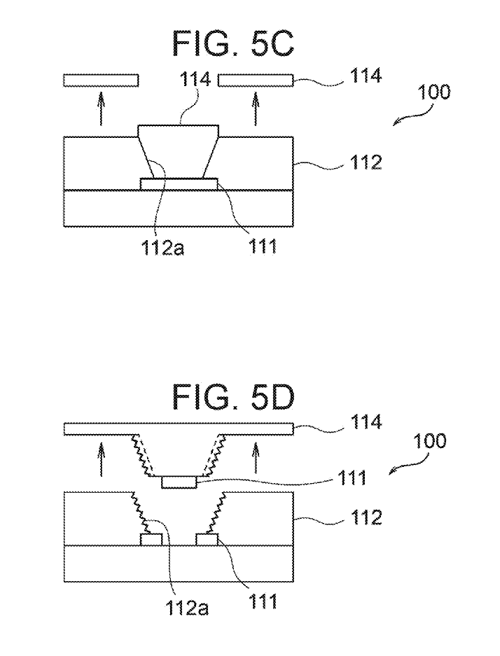

More particularly, for example, as shown in FIG. 5A, in the peeling test, when the plated layer 114 is peeled off from both a bottom and a side wall of the via hole 112a formed in the insulating layer 112 of a specimen 100, it is determined to be a defective (that is, defective via bottom+defective side wall). The pattern shown in FIG. 5A is assumed to occur when the adhesiveness is lower at both the via bottom (the conductive layer 111 and the plated layer 114) and the side wall (the insulating layer 112 and the plated layer 114).

Also, as shown in FIG. 5B, when the conductive layer 111 as well as the plated layer 114 is torn off in the peeling test, it is determined to be a defective (that is, defective side wall). The pattern shown in FIG. 5B is assumed to occur when the adhesiveness is insufficient at the side wall (the insulating layer 112 and the plated layer 114) while the adhesiveness between Cu at the via bottom (the conductive layer 111 and the plated layer 114) has no problem.

On the other hand, as shown in FIG. 5C, in the peeling test, when the plated layer 114 is peeled off from the surface of the insulating layer 112 while the plated layer 114 is kept to adhere to the via 112a, it is determined to be a non-defective. The pattern shown in FIG. 5C is assumed to occur when the adhesiveness inside the via hole (the via bottom and the side wall) is extremely high.

Also, as shown in FIG. 5D, in the peeling test, when the via 112a demonstrates the cohesive failure in the insulating layer 112 to the extent that the via 112a considerably collapses, it is determined to be a non-defective.

As shown in Table 1-2, in the Referential Example 1, the peel strength is 0.42 kg/cm. Also, as for the via connection strength in this specimen, the ratio of the non-defective items is 100%. In this specimen, the surface roughness Raₜₒₚ is 200 nm and the roughness of the side wall Raᵥᵢₐ is also 200 nm.

This is because a chemical solution used in the wet desmear treatment has a function to roughen the surface of the epoxy resin so as to similarly roughen the surface of the substrate as well as the side wall of the via hole. Also, as the surface of the substrate is roughened, the Cu plated layer based on the non-electrolytic plated layer bites into the roughened surface of the substrate so as to increase the adhesiveness.

However, in the specimen in the Referential Example 1, the opening portion of the via hole is largely corroded and the opening of 50 μm, which was originally opened by the CO₂ laser, is enlarged to 60 μm.

Yet furthermore, when the resist pattern formed on the substrate is observed, the patterns are observed to collapse everywhere. This is because the footprint (mounting surface) of the resist becomes smaller due to the larger surface roughness so as to lower the adhesiveness.

As described above, when the wet desmear treatment is combined with the seed layer forming process using the non-electrolytic plating as the Referential Example 1, although the adhesiveness between the conductive layer and the insulating layer can be ensured to some extent due to the anchor effect, it makes it difficult to fabricate the fine wiring substrate due to the roughened surface of the insulating layer.

In the Comparative Example 1, the peel strength is 0.45 kg/cm. Also, as for the via connection strength in this specimen, the ratio of the non-defective items is 65%, which is found to be inferior in quality.

This is because when the surface of the insulating layer becomes uneven or irregular due to the corrosive action or corrosion by the permanganic acid during the wet desmear treatment, incoming metal particles from the sputtering source deposit unevenly on the uneven surface, and thus the Cu seed film is not formed in a shadowed portion of the uneven surface. Also, the surface roughness Raₜₒₚ is 200 nm and the roughness of the side wall Raᵥᵢₐ is also 200 nm because of the similar reason to those in the Referential Example 1.

It should be noted that the incoming metal particles from the sputtering source acquires higher kinetic energy and to be driven into the surface of the resin. At this point, the sputtering using solid metal is considered to have an action to slightly drive into (hit) the surface layer of the resin. For this reason, generally the sputtering using the solid metal demonstrates the higher peel strength than the non-electrolytic plating seed.

However, in the specimen of the Comparative Example 1, the surface for mounting the sheet layer is uneven to compensate with the driving action. For this reason, the improvement in the peel strength in the Comparative Example 1 with respect to the Referential Example 1 stays to be 0.03 kg/cm. Moreover, as the surface is roughened, a gap is created at the plated layer based on the sputtered seed layer so as to lower the adhesiveness.

Yet furthermore, similarly to the Referential Example 1, in the specimen in the Comparative Example 1, the opening portion of the via hole is largely corroded and the opening of 50 μm, which was originally opened by the CO₂ laser, is enlarged to 60 μm.

Still yet furthermore, when the resist pattern formed on the substrate is observed, the patterns are observed to collapse everywhere. This is because the footprint of the resist becomes smaller due to the larger surface roughness so as to lower the adhesiveness.

As described above, when the wet desmear treatment is combined with the seed layer forming process using the sputtering as the Comparative Example 1, the adhesiveness between the conductive layer and the insulating layer cannot be ensured, and also it is difficult to fabricate the fine wiring substrate due to the roughened surface of the insulating layer.

In contrast, in the Working Example 1, the peel strength is 0.85 kg/cm. Also, as for the via connection strength in the specimen of the Working Example 1, the ratio of the non-defective items is 100%, which is found to be superior in quality. This is because the color center is generated in the surface layer of the resin by the irradiation of the ultra violet light having the wavelength equal to or less than 220 nm, and the activated portion thereof captures the sputter particles to form the seed layer. In this way, the firm binding force is created beyond the mere deposition of the incoming metal particles from the sputtering source or the mere driving thereof.

As described above, when the photo desmear treatment is combined with the seed layer forming process using the sputtering as the Working Example 1, the sputtered seed film formed on the surface of the resin becomes extremely firm so as to demonstrate a higher peeling strength than the sputtered seed film formed in combination with the wet desmear treatment. For this reason, as also shown in the Table 1-2, the improvement in the peel strength in the Working Example 1 with respect to the Comparative Example 1 is significantly heighten by 0.4 kg/cm.

In addition, in the Working Example 1, the surface roughness Raₜₒₚ is 120 nm and the roughness of the side wall Raᵥᵢₐ is 95 nm. This is because the ultra violet light has little function to roughen the surface, thus both the surface of the substrate and the side wall of the via hole are similarly prevented from being roughened.

Furthermore, in the specimen in the Working Example 1, the opening portion of the via hole is less corroded and the opening of 50 μm, which was originally opened by the CO₂ laser, stays to be 52 μm.

Yet furthermore, when the resist pattern formed on the substrate is observed, the patterns are observed to be excellent. This is because the footprint of the resist is sufficiently ensured due to the smaller surface roughness so as to maintain the adhesiveness.

As described above, when the photo desmear treatment is combined with the seed layer forming process using the sputtering as the Working Example 1, it makes it possible to ensure the adhesiveness between the conductive layer and the insulating layer without the surface of the resin layer being roughened. In addition, as the surface of the resin layer is not roughened, it also makes it possible to fabricate the fine wiring substrate.

In the Comparative Example 2, the peel strength is 0.40 kg/cm. Also, as for the via connection strength in this specimen, the ratio of the non-defective items is 72%, which is found to be inferior in quality. This is because the inside of the via hole (side wall), which is not subject to the protective action by the PET film (the protective film) becomes uneven due to the corrosive action by the permanganic acid during the wet desmear treatment, then incoming metal particles from the sputtering source deposit unevenly on the uneven surface, and thus the Cu seed film is not formed in a shadowed portion of the uneven surface.

Also, in the Comparative Example 2, the surface roughness Raₜₒₚ is 70 nm to be found smooth and the roughness of the side wall Raᵥᵢₐ is 169 nm. In this way, it is observed that the chemical solution does not contact the surface of the epoxy resin due to the protective action of the PET film (protective film) thus the surface of the epoxy resin is kept to be smooth. However, it is also observed that the side wall of the via hole is roughened by the chemical solution.

Yet furthermore, in the specimen in the Comparative Example 2, the opening portion of the via hole is largely corroded and the opening of 50 μm, which was originally opened by the CO₂ laser, is enlarged to 57 μm. In addition, the chemical solution stagnates due to the action of the protective layer. For this reason, the diameter at the bottom portion of the via hole becomes larger than the diameter at the opening portion of the via hole. Thus, it is observed in some cases the via hole has a shape in which the inside of the via hole is expanded.

It should be noted that, when the resist pattern formed on the substrate is observed, the patterns are observed to be excellent. This is because the footprint of the resist becomes larger due to the smaller surface roughness so as to maintain the adhesiveness.

As described above, even when the wet desmear treatment is combined with the seed layer forming process using the sputtering as the Comparative Example 2, it makes it possible to fabricate the fine wiring substrate as long as the PET film (protective film) is employed. However, it is impossible to ensure the adhesiveness between the conductive layer and the insulating layer. Instead, when the photo desmear treatment is combined with the seed layer forming process using the sputtering as the above described Working Example 1, it makes it possible to accomplish the fabrication of the fine wiring substrate while ensuring the adhesiveness between the conductive layer and the insulating layer even without the PET film (protective film) being used.

In contrast, in the Working Example 2, the peel strength is 0.62 kg/cm. Also, as for the via connection strength in the specimen of the Working Example 2, the ratio of the non-defective items is 100%, which is found to be superior in quality. This is because the inside of the via hole (side wall), which is not subject to the protective action of the PET film (protective film), is irradiated with the ultra violet light having the wavelength equal to or less than 220 nm to generate the color center inside the resin, and the generated color center firmly captures the incoming sputter particles from the sputtering source to intensify the adhesiveness.

In addition, in the Working Example 2, the surface roughness Raₜₒₚ is 75 nm, which is found to be smooth and the roughness of the side wall Raᵥᵢₐ is 70 nm, which is also found to be smooth. This is because the surface of the epoxy resin is kept to be smooth due to the protective action of the PET film (protective film), and also the inside of the via hole (side wall) is prevented from being roughened due to the ultra violet light irradiation.

Furthermore, in the specimen in the Working Example 2, the opening portion of the via hole is less corroded and the opening of 50 μm stays to be 51 μm. Thus, the sustainability of the via shape is higher.

Yet furthermore, when the resist pattern formed on the surface is observed, the patterns are observed to be excellent. This is because the footprint of the resist becomes larger due to the smaller surface roughness so as to maintain the adhesiveness.

As described above, when the photo desmear treatment is combined with the seed layer forming process using the sputtering and further the PET film (protective layer) is employed as the Working Example 2, it makes it possible to ensure the adhesiveness between the conductive layer and the insulating layer while preventing the surface of the insulating layer from being roughened to the minimum. In addition, as the surface of the resin layer is not roughened, it also makes it possible to fabricate the fine wiring substrate.

In the Comparative Example 3, the peel strength is 0.40 kg/cm. Also, as for the via connection strength in this specimen, the ratio of the non-defective items is 23%, which is found to be inferior in quality. This is because, as the via diameter is small, the permanganic acid does not enter the via hole so that the smear cannot be removed. The incoming metal particles from the sputtering source deposit on the surface on which the smear remains and the Cu plated layer is formed thereon. As a result, the adhesiveness is considerably lowered.

Also, in the Comparative Example 3, the surface roughness Raₜₒₚ is 70 nm, which is found to be smooth and the roughness of the side wall Raᵥᵢₐ is 120 nm. This is because the chemical solution does not contact the surface of the epoxy resin due to the protective action of the PET film (protective film) thus the surface of the epoxy resin is kept to be smooth, but on the other hand the side wall of the via hole is roughened by the chemical solution.

Yet furthermore, in the specimen in the Comparative Example 3, the opening portion of the via hole is largely corroded and the opening of 25 μm is enlarged to 30 μm. In addition, the chemical solution stagnates due to the action of the protective layer. For this reason, the diameter at the bottom portion of the via hole becomes larger than the diameter at the opening portion of the via hole. Thus, it is observed in some cases the via hole has a shape in which the inside of the via hole is expanded.

It should be noted that, when the resist pattern formed on the substrate is observed, the patterns are observed to be excellent. This is because the footprint of the resist becomes larger due to the smaller surface roughness so as to maintain the adhesiveness.

As described above, even when the wet desmear treatment is combined with the seed layer forming process using the sputtering as the Comparative Example 3, it makes it possible to fabricate the fine wiring substrate as long as the PET film (protective film) is employed. However, when the via diameter is relatively small, such as φ25 μm, the smear cannot be appropriately removed by the wet desmear treatment so as to fail to ensure the adhesiveness between the conductive layer and the insulating layer.

In contrast, in the Working Example 3, the peel strength is 0.62 kg/cm. Also, as for the via connection strength in the specimen of the Working Example 3, the ratio of the non-defective items is 100%, which is found to be superior in quality. This is because the inside of the via hole (side wall), which is not subject to the protective action of the PET film (protective film), is irradiated with the ultra violet light having the wavelength equal to or less than 220 nm to generate the color center inside the resin, and the generated color center firmly captures the incoming sputter particles from the sputtering source to intensify the adhesiveness.

In addition, in the Working Example 3, the surface roughness Raₜₒₚ is 80 nm, which is found to be smooth and the roughness of the side wall Raᵥᵢₐ is 90 nm, which is also found to be smooth. This is because the surface of the epoxy resin is kept to be smooth due to the protective action of the PET film (protective film), and the inside of the via hole (side wall) is prevented from being roughened due to the ultra violet light irradiation.

Furthermore, in the specimen in the Working Example 3, the opening portion of the via hole is less corroded and the opening of 25 μm stays to be 27 μm. Thus, the sustainability of the via shape is higher.

Still yet furthermore, when the resist pattern formed on the surface is observed, the patterns are observed to be excellent. This is because the footprint of the resist becomes larger due to the smaller surface roughness so as to maintain the adhesiveness.

As described above, when the photo desmear treatment is combined with the seed layer forming process using the sputtering and further the PET film (protective film) is employed as the Working Example 3, it makes it possible to ensure the adhesiveness between the conductive layer and the insulating layer while suppress the surface of the insulating layer from being roughened to the minimum. In addition, as the surface of the resin layer is not roughened, it also makes it possible to fabricate the fine wiring substrate. Moreover, even when the via diameter is relatively small, such as φ25 μm, by applying the photo desmear treatment, it makes it possible to appropriately remove the smear so as to ensure the adhesiveness between the conductive layer and the insulating layer.

In the Comparative Example 4, the peel strength is 0.45 kg/cm. Also, as for the via connection strength in this specimen, the ratio of the non-defective items is 87%, which is found to be inferior in quality. This is because, although the resin inside the via hole absorbs the ultra violet light, the action of the color center in the surface portion is small as the wavelength thereof is 254 nm so that the color center hardly captures the sputtered particles. As a result, the adhesiveness on the surface of the substrate and inner face of the via hole is lower.

Also, in the Comparative Example 4, the surface roughness Raₜₒₚ is 100 nm, which is found to be smooth and the roughness of the side wall Raᵥᵢₐ is 100 nm, which is also found to be smooth. This is because the ultra violet light has less function to roughen the surface so as to prevent the surface of the substrate as well as the side wall of the via hole from being roughened. Also, when the resist pattern formed on the substrate is observed, the patterns are observed to be excellent. This is because the footprint of the resist becomes larger due to the smaller surface roughness so as to maintain the adhesiveness.

As described above, when the photo desmear treatment using the ultra violet light having the wavelength of 254 nm is combined with the seed layer forming process using the sputtering as the Comparative Example 4, it makes it possible to fabricate the fine wiring substrate as the surface of the insulating layer is not roughened similarly to the above described Working Example 1. However, as the wavelength of the ultra violet light used in the photo desmear treatment is not equal to or less than 220 nm unlike the above described Working Example 1, it is impossible to cause the color center to be generated selectively in the surface layer of the resin so as to fail to heighten the adhesiveness between the conductive layer and the insulating layer.

As described above, when the photo desmear treatment using the ultra violet light having the wavelength equal to or less than 220 nm is combined with the seed layer forming process using the sputtering, it makes it possible to ensure the higher adhesiveness both on the surface of the insulating layer and inside the via hole so as to accomplish the substrate with higher reliability. Moreover, as the surface of the resin can be kept to be smooth, it makes it possible to form the resist pattern for forming the fine wiring in a stable manner so as to manufacture the fine wiring substrate with higher accuracy.

### (Wiring Substrate Manufacturing Device)

The above described manufacturing process of the wiring substrate can be implemented by a wiring substrate manufacturing device, which will be described below.

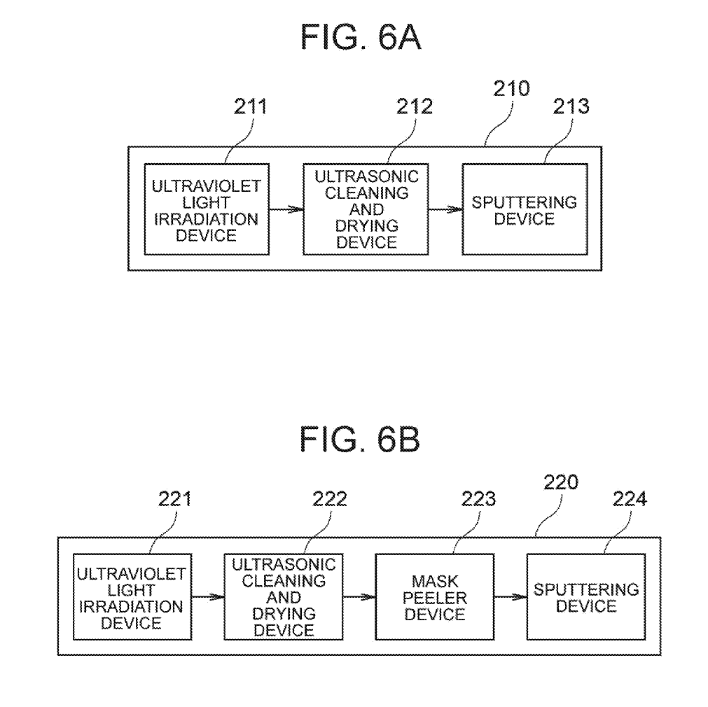

FIGS. 6A and 6B are schematic views showing exemplarily configurations of the wiring substrate manufacturing devices, respectively. In particular, FIG. 6A shows an exemplarily configuration of a wiring substrate manufacturing device 210 configured to manufacture a wiring substrate without the above described protective film being used, while FIG. 6B shows another exemplarily configuration of a wiring substrate manufacturing device 220 configured to manufacture a wiring substrate with the above described protective film being used.

The wiring substrate manufacturing device 210 comprises an ultra violet light irradiation device 211, an ultrasonic cleaning and drying device 212, and a sputtering device 213. The ultra violet light irradiation device 211 perform the ultra violet light irradiation process in the photo desmear treatment to a workpiece (that is, a wiring substrate material). The ultrasonic cleaning and drying device 212 performs the ultrasonic vibration process (ultrasonic cleaning process) as the physical vibration imparting process, and subsequently performs the drying process for drying the workpiece. The sputtering device 213 employs the sputtering method and performs a process for forming the seed layer on a surface of the workpiece to which the photo desmear treatment has been applied.

The wiring substrate manufacturing device 220 comprises an ultra violet light irradiation device 221, an ultrasonic cleaning and drying device 222, a mask peeler device 223, and a sputtering device 224. The ultra violet light irradiation device 221 and the ultrasonic cleaning and drying device 222 are similar to the ultra violet light irradiation device 211 and the ultrasonic cleaning and drying device 212, respectively. The mask peeler device 223 perform a process for removing a protective film from a workpiece to which the photo desmear treatment has been applied. The sputtering device 224 employs the sputtering method and performs a process for forming the seed layer on a surface the workpiece from which the protective film has been removed.

According to any of the above described wiring substrate manufacturing devices 210 and 220, it makes it possible to accomplish the fabrication of the wiring substrate that is capable of ensuring the adhesiveness between the seed layer and the insulating layer with a higher reliability.

It should be noted that, in FIGS. 6A and 6B, each of the ultra violet light irradiation devices 211 and 221 corresponds to an ultra violet light irradiation unit, each of the ultrasonic cleaning and drying devices 212 and 222 corresponds to a vibration imparting unit, and each of the sputtering devices 213 and 224 corresponds to a seed layer forming unit.

### (Modifications)

Although the above embodiments have been described in the case in which the seed layer is formed by using the sputtering method, the present embodiment is not limited to those using the sputtering method. For example, the seed layer may be formed by using the ion plating method. The similar effect can be also obtained to the case in which the seed layer is formed by using the sputtering method. In other words, the similar effect is also obtainable to the above described embodiments as long as a technique for forming the seed layer by causing the material particles (metal particles) to collide against and adhere to the insulating layer, such as the sputtering method or the ion plating method, is employed.

Although specific embodiments are described above, these embodiments are merely illustrative in nature and are not intended to limit the scope of the present invention. The apparatuses and the methods described in the present specification can be implemented in embodiments aside from those described above. Omissions, substitutions, and modifications can be made, as appropriate, to the embodiments described above without departing from the scope of the present invention. An embodiment with such omissions, substitutions, and modifications is encompassed by what is described in the claims and any equivalent thereof and falls within the technical scope of the present invention.

### REFERENCE SIGNS LIST

10: Insulating Layer
11: Conductive Layer
12: Insulating Layer
12a: Via Hole
13: Seed Layer
14: Plated Layer
C: Color Center
L: Laser
R: Resist Pattern
S: Smear
T: Target Particles

1. A method of manufacturing a wiring substrate, comprising:
a first step of forming a through hole on a wiring substrate material having a conductive layer and an insulating layer laminated on the conductive layer, the through hole penetrating through the insulating layer;
a second step of applying a desmear treatment to the wiring substrate material by irradiating the wiring substrate material in which the through hole is formed with ultra violet light having a wavelength equal to or less than 220nm and causing a binding defect to be generated in a surface of the insulating layer;
a third step of forming a seed layer on the insulating layer by causing material particles to collide against and drive into the surface of the insulating layer to which the desmear treatment is applied and in which the binding defect is generated; and
a fourth step of forming a plated layer made of a conductive material on the seed layer by an electrolytic plating.

2. The method of manufacturing the wiring substrate according to claim 1, wherein, in the third step, the seed layer is formed by a sputtering method.

3. The method of manufacturing the wiring substrate according to claim 1, wherein, in the third step, the seed layer is formed by an ion plating method.

4. The method of manufacturing the wiring substrate according to claim 1, wherein
the insulating layer is made of a resin containing a particulate filler, and
the second step includes:
a step of irradiating the wiring substrate material with the ultra violet light; and
a step of imparting a physical vibration to the wiring substrate material irradiated with the ultra violet light.

5. The method of manufacturing the wiring substrate according to claim 1, wherein, in the second step,
the wiring substrate material is irradiated with the ultra violet light while heating the wiring substrate material in an atmosphere of a processing gas containing oxygen.

6. The method of manufacturing the wiring substrate according to claim 1, wherein
the first step is a step of forming the through hole in the wiring substrate material having a protective layer on the insulating layer, the through hole penetrating through the protective layer and the insulating layer,
in the second step, the desmear treatment is applied to an inside of the through hole by irradiating the wiring substrate material with the ultra violet light with the protective layer serving as a mask, and
in the third step, the seed layer is formed after removing the protective layer.

7. The method of manufacturing the wiring substrate according to claim 6, wherein
the first step includes:
a step of forming the protective layer on the insulating layer; and
a step of forming the through hole penetrating through the protective layer and the insulating layer.

8. A wiring substrate manufactured by any one of the methods of manufacturing the wiring substrate according to claim 1.

9. A wiring substrate manufacturing device, comprising:
an ultra violet light irradiation unit configured to irradiate a wiring substrate material with ultra violet light having a wavelength equal to or less than 220 nm, the wiring substrate material having a conductive layer, an insulating layer made of a resin containing a particulate filler and laminated on the conductive layer, and a though hole being formed to penetrate through the insulating layer, and to cause a binding defect to be generated in a surface of the insulating layer;
a vibration imparting unit configured to impart physical vibration to the wiring substrate material irradiated with the ultra violet light by the ultra violet light irradiation unit; and
a seed layer forming unit configured to form a seed layer on the insulating layer by causing material particles to collide against and drive into the surface of the insulating layer to which the desmear treatment is applied and in which the binding defect is generated by the ultra violet light irradiation unit and the vibration imparting unit.

10. A sputtering device, comprising:
a unit configured to form a seed layer on a surface of an insulating layer of a wiring substrate material by causing material particles to collide against and drive into the surface of the insulating layer,
the wiring substrate material having a conductive layer, the insulating layer made of a resin containing a particulate filler and laminated on the conductive layer, and a though hole being formed to penetrate through the insulating layer, and
a binding defect being generated on the surface of the insulating layer by a desmear treatment to irradiate the wiring substrate material on which the seed layer is to be formed with ultra violet light having a wavelength equal to or less than 220 nm and to impart physical vibration to the wiring substrate material.
